(19) United States
(12) Patent Application Publication
(10) Pub. No.: US 2008/0002373 A1
(43) Pub. Date: Jan. 3, 2008

(54) PRINTED CIRCUIT BOARD

(75) Inventors: Nobuhiro ARAI, Tokyo (JP); Akihiro Tanaka, Aichi (JP)

Correspondence Address: YOUNG & THOMPSON, 745 SOUTH 23RD STREET, 2ND FLOOR, ARLINGTON, VA, 22202, US

(73) Assignee: NEC CORPORATION, TOKYO (JP)

(21) Appl. No.: 11/764,439

(22) Filed: Jun. 18, 2007

(30) Foreign Application Priority Data
Jul. 3, 2006 (JP) 2006-183025

(51) Int. Cl. H05K 1/14

(52) U.S. Cl. 361/737

(57) ABSTRACT

A printed circuit board comprises a high-speed DRAM and a memory controller mounted thereon. The high-speed DRAM is connected to the memory controller by memory bus wiring. The printed circuit board further comprises a power supply pattern connected to the memory bus wiring via a parallel terminal end resistor. A series circuit is formed by serially connecting, between the power supply pattern and a ground pattern, a capacitor and a resistor having a resistance value substantially equal to a characteristic impedance of the power supply pattern.

This application claims priority to prior application JP 2006-183025, the disclosure of which is incorporated herein by reference.

### BACKGROUND OF THE INVENTION

1. Field of the Invention

The present invention relates to a printed circuit board, and in particular to a printed circuit board for mounting a circuit such as a DDR-SDRAM capable of high speed operation.

2. Related Background Art

A printed circuit board, on which a DRAM such as a DDR-SDRAM (Double-Data-Rate Synchronous Dynamic Random Access Memory) capable of high speed operation is mounted, may sometimes cause malfunction due to high speed operation of the DRAM.

An SSTL_{—}2 (Stub Series Terminated Logic for 2.5 V) interface according to JEDEC (Joint Electron Device Engineering Council) specifications is employed in a DRAM capable high speed operation (hereafter sometimes referred to as the high-speed DRAM) such as a DDR-SDRAM, for the purpose of eliminating deterioration of signals due to reflection or noise caused by increased frequency. In this SSTL_{—}2 interface, a termination voltage is specified, and a terminal end of memory bus wiring is sometimes connected to a power supply pattern via a resistor to optimize signal waveforms. In the following description, the termination voltage and the power supply pattern are sometimes referred as the VTT voltage and the VTT power supply pattern, respectively.

When a signal is transmitted through memory bus wiring in this connection state, electrical power is consumed by the resistor. The VTT voltage will vary when the memory bus simultaneously makes transition to ON or OFF. The operating frequency of the high-speed DRAM is as high as 100 MHz or more. Therefore, the fluctuation of the VTT voltage will cause noise according to the operating frequency of the high-speed DRAM.

A low capacitance capacitor with high time responsiveness is sometimes arranged between the VTT power supply pattern and a GND (Ground) pattern as a countermeasure against the noise. When the operating frequency is 100 MHz or higher, a commonly used low capacitance capacitor will present high impedance due to parasitic inductance. Therefore, the low capacitance capacitor is not effective enough as the countermeasure against high frequency noise.

On the other hand, high frequency noise generated in the VTT power supply pattern by operation of the memory bus of the high-speed DRAM will enter the memory bus wiring via the above-mentioned resistor, affecting the waveform quality or causing malfunction of the high-speed DRAM such as direct radiation to other signals or a power supply.

Patent Documents 1 to 4 mentioned below, for example, disclose technologies for other purposes than the stable operation of the high-speed DRAM, for example for the purpose of reducing radiation noise from a printed circuit board or a printed wiring board. Patent Document 1 (Japanese Patent No. 3036629) describes a printed wiring board for use in electronic equipment such as information equipment. It is particularly described in Patent Document 1 that a first capacitor is disposed in a periphery of a printed wiring board having a power supply layer and a ground layer to lower the reflectance of electrical resonance current, while a second capacitor is disposed in the vicinity of a power supply pin of an active element mounted on the printed wiring board to suppress loop current flowing between the active element and the first capacitor.

Patent Document 2 (Japanese Patent No. 3055136) describes a printed wiring board for use in electronic equipment such as an information processing device and a communication device. Patent Document 2 particularly describes a technique to connect in parallel series circuits composed of a plurality of capacitors or a plurality of capacitors and resistors between a power supply layer and a ground layer, whereby the inductance between the power supply layer and the ground layer can be reduced and the radiation of unnecessary electromagnetic waves due to voltage fluctuation between the power supply layer and the ground layer can be suppressed.

Patent Document 3 (Japanese Laid-Open Patent Publication No. H10-275981) discloses a multilayer board having capacitor means for channeling high frequency current flowing through a power supply layer to a ground layer. This capacitor means has a capacitor and a resistor connected in series to this capacitor.

Patent Document 4 (Japanese Laid-Open Patent Publication NO. 2004-158605) discloses a printed wiring board including a snubber circuit formed by serially connecting a resistor and a capacitor between a power supply layer and a signal layer.

However, none of the techniques disclosed in Patent Documents 1 to 4 aims at stable operation of a high-speed DRAM.

### SUMMARY OF THE INVENTION

It is an exemplary object of the present invention to provide a printed circuit board having a high-speed DRAM and a memory controller mounted thereon and capable of realizing stable operation of the high-speed DRAM.

It is further exemplary object of the present invention to provide a method of reducing high frequency noise generated in a power supply pattern due to operation of the high-speed DRAM or memory controller.

The present invention is applied to a printed circuit board having a high-speed DRAM and a memory controller mounted thereon, in which the high-speed DRAM and the memory controller are connected to each other by means of memory bus wiring. The printed circuit board has a power supply pattern connected to the memory bus wiring via a parallel terminal end resistor. The printed circuit board further includes a series circuit formed by serially connecting, between the power supply pattern and a GND pattern, a capacitor and a resistor having a resistance value substantially equal to a characteristic impedance of the power supply pattern.

Thus, the printed circuit board according to the present invention contributes to stable operation of the high-speed DRAM by connecting and arranging, between the power supply pattern and the GND pattern, a series circuit composed of a capacitor and a resistor so that any high frequency noise generated in the power supply pattern due to operation of the high-speed DRAM or memory controller is consumed by the resistor while the high frequency noise is propagated through the power supply pattern.

### BRIEF DESCRIPTION OF THE DRAWINGS

FIG. 1A shows a basic configuration of a printed circuit board for embodying the present invention, while FIG. 1B shows an equivalent circuit of the basic configuration shown in FIG. 1A;

FIG. 2 is a diagram for explaining a printed circuit board according to an exemplary embodiment of the present invention;

FIG. 3A shows an example of a printed circuit board in a related art, while FIG. 3B shows an example of a printed circuit board to which the present invention is applied;

FIG. 4 is a diagram showing a relationship between a frequency of malfunctions and a quantity of series circuits composed of a capacitors and a resistor connected and arranged in the vicinity of a high-speed DRAM according to the present invention;

FIG. 5 is a diagram showing a model circuit board for explaining operation of a printed circuit board in a related art;

FIG. 6 is a diagram showing a model circuit board for explaining operation of a printed circuit board according to the present invention;

FIG. 7 is a diagram showing the result of measuring time variation in the coefficient of reflection of the model circuit board shown in FIG. 5 from the first layer side by time domain reflectometry (TDR), and converting the coefficient of reflection into a characteristic impedance; and

FIG. 8 is a diagram for explaining the result of measuring time variation in the coefficient of reflection of the model circuit board of the present invention shown in FIG. 6 from the first layer side by TDR, and converting the coefficient of reflection into a characteristic impedance.

### DESCRIPTION OF THE EXEMPLARY EMBODIMENTS

Before describing exemplary embodiments of the present invention, features of the present invention will be described.

The present invention is applicable to a printed circuit board or a printed wiring board having a multilayer structure on which a high-speed operating circuit such as a DDR-SDRAM (Double-Data-Rate Synchronous Dynamic Random Access Memory) required to operate at low voltage and high speed is mounted. When noise enters a power supply pattern for high-speed DRAM to which the parallel terminal ends of memory bus wiring is connected, the printed circuit board according to the present invention prevents the noise from being propagated to other signal lines or power supply patterns, causing malfunction of the high-speed operating circuit. For this purpose, a series circuit formed by serially connecting a capacitor and a resistor having a substantially equivalent impedance to a characteristic impedance of the high-speed DRAM power supply pattern is connected and arranged between the high-speed DRAM power supply pattern and a GND (ground) pattern. According to this configuration, any noise that has entered or occurred in the high-speed DRAM power supply pattern can be consumed by the series circuit, and the malfunction of the high-speed operating circuit can be prevented effectively.

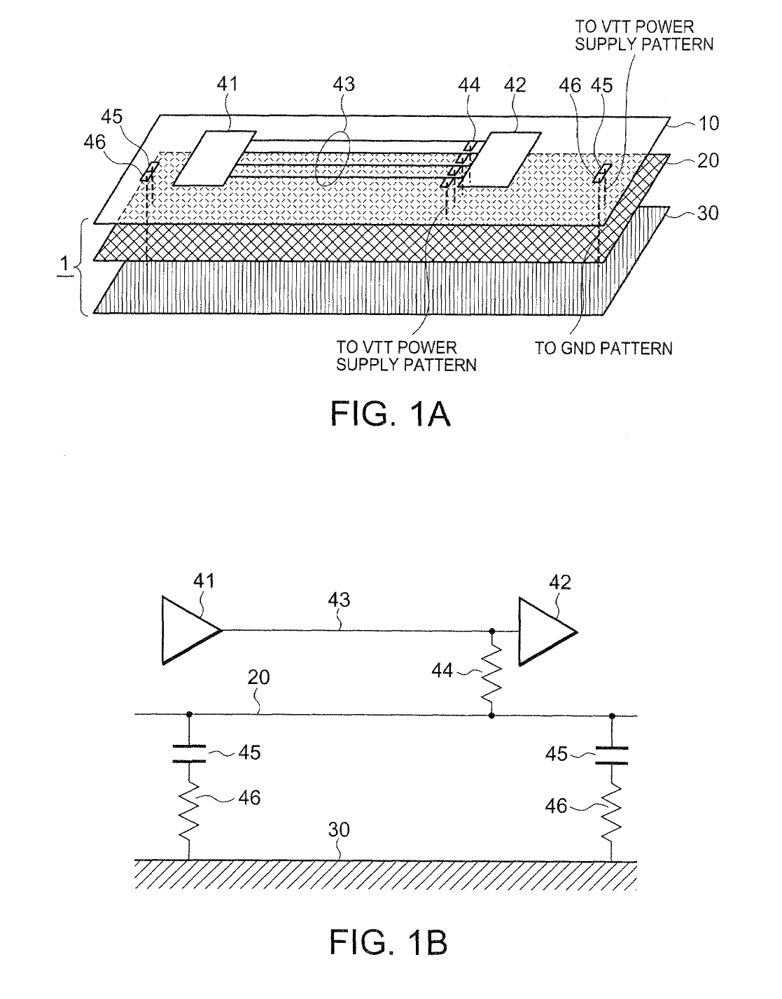

A basic configuration for realizing this will be described with reference to FIGS. 1A and 1B.

FIG. 1A shows a basic configuration of a printed circuit board for embodying the present invention, while FIG. 1B shows an equivalent circuit of FIG. 1A. In FIG. 1A, for easier comprehension, a printed circuit board 1 having a multilayer structure is shown being divided into a top surface portion 10, a VTT power supply pattern 20 under the top surface portion 10, and a GND pattern 30 under the VTT power supply pattern 20.

A memory controller 41 and a high-speed DRAM 42 are mounted on the top surface portion 10 of the printed circuit board 1, and these are connected to each other by memory bus wiring 43 formed of a plurality wiring lines. One end of each parallel terminal end resistor 44 is connected to the corresponding wiring line of the memory bus wiring 43 at a position closer to the high-speed DRAM 42, while the other end of the parallel terminal end resistor 44 is connected to the VTT power supply pattern 20. FIG. 1A shows a plurality of parallel terminal end resistors 44, whereas FIG. 1B shows these parallel terminal end resistors collectively as one resistor indicated by the reference numeral 44.

The printed circuit board 1 having the features described above is configured as described below.

(1) A series circuit composed of the capacitor 45 and the resistor 46 is connected and arranged between the VTT power supply pattern 20 and the GND pattern 30. A resistance value R of the resistor 46 is selected to be substantially equal to a characteristic impedance Z₀ of the VTT power supply pattern 20.

(2) The series circuit consumes high frequency noise which has entered or has occurred in the VTT power supply pattern 20.

(3) This prevents malfunction of the memory controller 41 and the high-speed DRAM 42, that is caused by propagation of noise from the VTT power supply pattern 20 to the memory bus wiring 43 through the parallel terminal end resistor 44, or by noise entering the memory bus wiring 43 or another power supply pattern due to cross-talk of the VTT power supply pattern 20 with the memory bus wiring 43 or the other power supply pattern. As a result, the high-speed operating circuits such as the high-speed DRAM 42 in the printed circuit board 1 are allowed to operate stably.

Exemplary embodiments of the present invention will be described below.

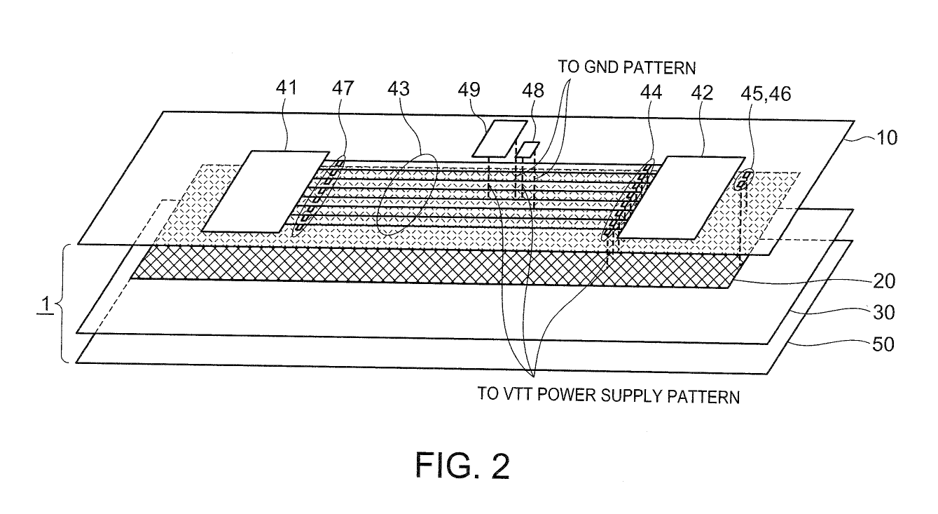

Referring to FIG. 2, a multilayer-structure printed circuit board 1 having a memory controller 41 and a high-speed DRAM 42 mounted thereon is shown as an exemplary embodiment of the present invention. For easier comprehension also in FIG. 2, the printed circuit board 1 is shown being divided into a top surface portion 10, a VTT power supply pattern 20, a GND pattern 30, and a rear surface portion 50. In an actual printed circuit board, the memory controller 41 and the high-speed DRAM 42 in FIG. 2 occupy a partial region in the printed circuit board. There are actually other power supply patterns, GND patterns, and signal wiring lines than those shown in FIG. 2. FIG. 2 shows those parts necessary for explaining the exemplary embodiment of the present invention.

In FIG. 2, the memory controller 41 outputs signals such as clocks, data, addresses, and commands. The memory bus wiring 43 is a conductor to electrically connect the memory controller 41 and the high-speed DRAM 42, and is composed of a plurality of wiring lines. The memory bus wiring 43 is provided with a resistor (so-called damping resistor) 47 which is inserted and connected to the vicinity of the memory controller 41, in order to obtain a desirable waveform or to eliminate radiation noise attributable to the memory bus wiring 43. The high-speed DRAM 42 serving as a receiver and a data bus are provided with a resistor 44 (hereafter referred to as the parallel terminal end resistor) which is connected and arranged between the memory bus wiring 43 and the power supply pattern 20, in the vicinity of the high-speed DRAM 42, in order to obtain a desirable waveform. The damping resistor 47 and the parallel terminal end resistor 44 are provided for each of the wiring lines of the memory bus wiring 43. The parallel terminal end resistor 44 has a substantially same resistance value as a characteristic impedance of the memory bus wiring 43. VTT power supply generated by a VTT power supply generating IC (Integrated Circuit) 49 is connected to a VTT power supply pattern 20, and a capacitor 48 is disposed between the VTT power supply pattern 20 and the GND pattern 30, in the vicinity of the connection part.

According to this exemplary embodiment, a series circuit composed of a capacitor 45 and a resistor 46 having a substantially same resistance value R as a characteristic impedance Z₀ of the VTT power supply pattern 20 is connected and arranged between the VTT power supply pattern 20 and the GND pattern 30. Assuming that the VTT power supply pattern 20 is a transmission line, the characteristic impedance Z₀ thereof was calculated to be about 10Ω. Therefore, in this exemplary embodiment, the resistance value R of the resistor 46 is set to 10Ω, and the capacitance of the capacitor 45 is set to 0.1 μF.

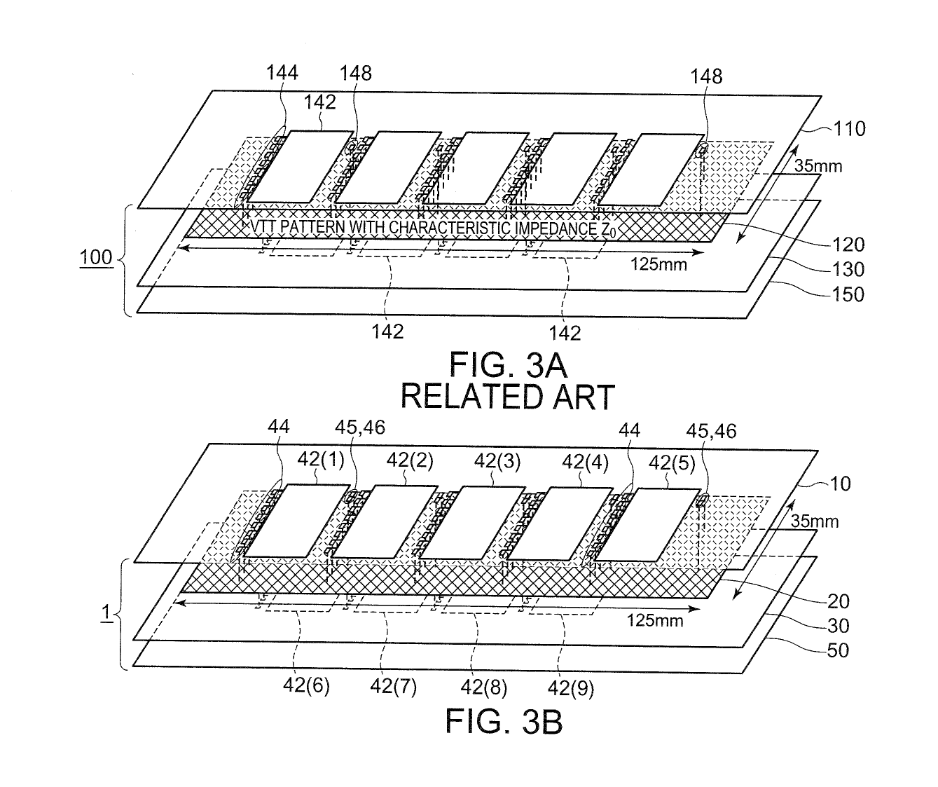

Referring to FIGS. 3A and 3B, an example of applying the present invention to an actual printed circuit board will be described. In FIGS. 3A and 3B, similarly to FIG. 2, those parts required to explain the exemplary embodiment of the present invention are shown, while the memory controller and the memory bus wiring are omitted.

FIG. 3A shows a printed circuit board in a related art. For easier comprehension, a multilayer-structure printed circuit board 100 is shown therein being divided into a top surface portion 110, a VTT power supply pattern 120, a GND pattern 130, and a rear surface portion 150.

In FIG. 3A, the VTT power supply pattern 120 is formed into a rectangle having a long side of 125 mm and a short side of 35 mm, and is disposed in an inner layer of the printed circuit board 100. The high-speed DRAMs (DDR-SDRAM) 142 are mounted, five on the top surface portion 110, and four on the rear surface portion 150. A group of eight parallel terminal end resistors 144 is disposed in the vicinity of each of these nine high-speed DRAMs 142. This means that 72 (=8×9) parallel terminal end resistors 144 in total are connected between the wiring lines of the memory bus wiring (not shown) and the VTT power supply pattern 120. A capacitor 148 is arranged in the vicinity of each of the nine high-speed DRAMs 142, and thus nine capacitors in total are arranged and connected between the VTT power supply pattern 120 and the GND pattern 130 for the purpose of stabilizing the VTT power supply.

This printed circuit board 100 is instantaneously supplied with large electric current via the parallel terminal end resistors 144 along with output of a signal from a memory controller (not shown), whereby noise is generated in the VTT power supply pattern 120, resulting in occurrence of a memory access error. It is believed that the occurrence of a memory access error is attributable to the face that this noise enters the memory bus wiring through the parallel terminal end resistor 144, or the noise enters the memory bus wiring or another power supply pattern (not shown) due to cross-talk between the VTT power supply pattern 120 and the memory bus wiring or the other power supply pattern.

In contrast, in FIG. 3B, a series circuit formed by serially connecting a capacitor 45 and a resistor 46, instead of the capacitor 148 of FIG. 3A, is arranged and connected between the VTT power supply pattern 20 and the GND pattern 30, in the vicinity of a high-speed DRAM (DDR-SDRAM) 42. It is found that this can effectively reduce the occurrence of the memory access error. The resistance value R of the mounted resistor 46 is set to 10Ω, while the capacitance of the capacitor 45 is set to 0.1 μF. The resistance value of 10Ω is appropriate in this circuit for the following reasons. Calculation of the characteristic impedance was conducted on the rectangular VTT power supply pattern 20 having a long side of 125 mm and a short side of 35 mm, in combination with the GND pattern 30. The calculation found that the characteristic impedance of the VTT power supply pattern 20 as a transmission path was 0.5Ω. Therefore, a small chip resistor with a characteristic impedance of 10Ω was selected as an inexpensive and easy-to-obtain resistor having a characteristic impedance close to 0.5Ω. Up to nine series circuits composed of such resistor and a capacitor are arranged and connected between the VTT power supply pattern 20 and the GND pattern 30. In this case, it can be considered that these series circuits are connected in parallel between the VTT power supply pattern 20 and the GND pattern 30, and thus the combined resistance value by the parallel connection can be about 1Ω close to 0.5Ω.

Also in FIG. 3B, the VTT power supply pattern 20 is formed into a rectangle having a long side of 125 mm and a short side of 35 mm, and is disposed in an inner layer of the printed circuit board 1. High-speed DRAMs (DDR-SDRAM) 42 are mounted, five on the top surface portion 10, and four on the rear surface portion 50. Eight parallel terminal end resistors 44 are arranged in the vicinity of each of the nine high-speed DRAMs 42. This means that 72 (=8×9) parallel terminal end resistors 44 in total are connected between the wiring lines of the memory bus wiring and the VTT power supply pattern 20.

Although FIG. 3B shows the series circuits provided in association with the high-speed DRAMs 42 on the top surface, it will be obvious that series circuits provided in association with the high-speed DRAMs 42 on the rear surface can be connected and arranged between the GND pattern 30 and the VTT power supply pattern 20, similarly to those on the top surface.

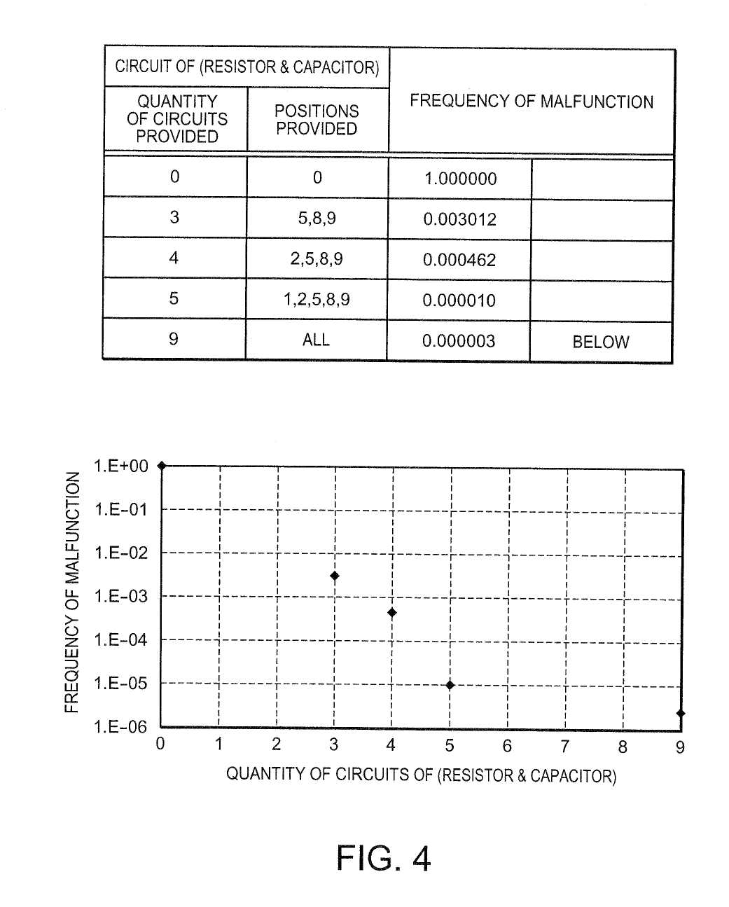

FIG. 4 shows a relationship between a quantity of series circuits each composed of the capacitor 45 and the resistor 46 and arranged in the vicinity of the high-speed DRAMs 42, and a frequency of malfunctions (memory access errors). In FIG. 4, the numerals from 1 to 9 indicated as “Positions Provided” respectively represent the high-speed DRAMs designated with the reference numeral 42 with the corresponding numerical values in the brackets in FIG. 3B. It can be seen that the frequency of malfunctions is reduced as the quantity of the series circuits is increased. When the series circuits are provided to all the nine high-speed DRAMs 42 on the top and rear surfaces, the memory access error is eliminated substantially completely. This reveals that the series circuits are effective to eliminate the malfunction of the high-speed DRAMs 42.

Returning to FIGS. 1A and 1B, the operation of the present invention will be described.

Referring to FIG. 1B, when a signal output by the memory controller 41 reaches the parallel terminal end resistor 44 via the memory bus wiring 43, electric current will flow from the memory bus wiring 43 to the VTT power supply pattern 20 if the signal transmits from low to high, whereas electric current will flow from the VTT power supply pattern 20 to the memory bus wiring 43 if the signal transmits from high to low. In either case, the charge amount of the VTT power supply is instantaneously changed in accordance with the signal transition speed, and hence high frequency noise is generated in the VTT power supply pattern 20. When this high frequency noise reaches the series circuit composed of the capacitor 45 and the resistor 46 between the VTT power supply pattern 20 and the GND pattern 30, the high frequency noise is consumed by the series circuit.

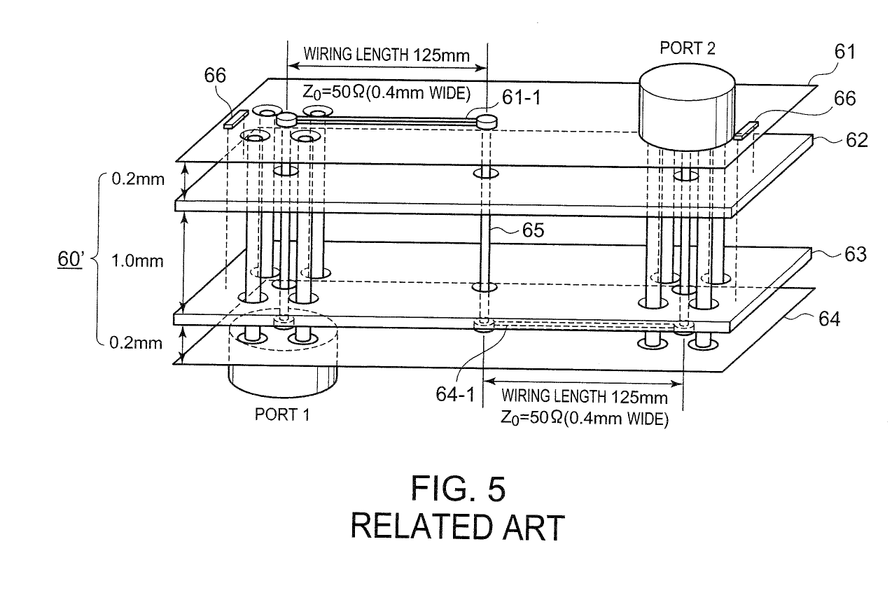

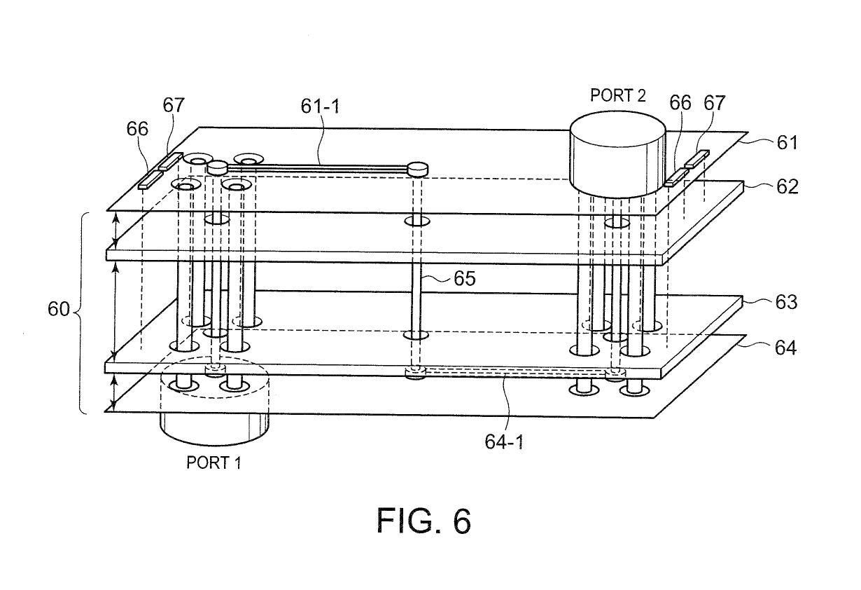

This principle will be described on the basis of model circuit boards shown in FIGS. 5 and 6.

FIG. 5 shows a printed circuit board 60′ composed of four layers: first layer 61 as a top surface portion, a second layer 62 formed by a solid GND pattern, a third layer 63 formed by a solid pattern connected to nowhere (floating solid pattern), and a fourth layer 64 as a rear surface portion. This printed circuit board has no series circuit according to the present invention.

As shown in FIG. 5, the first layer 61 and the fourth layer 64 are respectively provided with wiring 61-1 and wiring 64-1 both having a characteristic impedance of 50Ω. The wiring 61-1 of the first layer 61 and the wiring 64-1 of the fourth layer 64 are connected to each other through a via-hole 65 formed in the second layer (solid GND pattern) 62 and the third layer (floating solid pattern) 63 at a longitudinally central portion of the substrate.

SMA connectors indicated herein as ports 1 and 2 are attached to the opposite ends of the substrate. Signal lead lines of the SMA connectors are connected to the wiring 61-1 and the wiring 64-1 having a characteristic impedance of 50Ω in the first layer 61 and the fourth layer 64, respectively, while GND lead lines of the SMA connectors are connected to the solid GND pattern of the second layer 62. The third layer 63 can be deemed as a solid power supply pattern by connecting the solid GND pattern of the second layer 62 to the floating solid pattern of the third layer 63 by means of the capacitors 66 at the opposite ends of the substrate.

A system is established in the configuration as described above such that when a signal is input from the first layer 61, the signal will be propagated through the wiring 64-1 of the fourth layer 64 via the via-hole 65 at a longitudinal center of the substrate, and consumed by the 50Ω resistor. Since there is no power supply return path in the vicinity of the via-hole 65, return current from the solid GND pattern of the second layer 62 generated along with the propagation of the signal through the wiring 61-1 is propagated through the solid GND pattern in the rightward direction as viewed in FIG. 5.

The characteristic impedance of the solid power supply pattern is denoted by Z₀, and the capacitance of the capacitor 66 between the solid power supply pattern and the GND pattern is denoted by C. The impedance of the capacitor 66 is thus represented as 1/ωC (where ω=2πf, and f is a frequency Hz).

Thus, the coefficient of reflection between the solid power supply pattern and the capacitor 66 is represented as (1/ωC−Z₀)/(1/ωC+Z₀). Accordingly, the reflector voltage V1′ in this portion is represented, as a function of a progressive wave voltage V1, by the equation:

V1′=V1×[(1/ωC−Z₀)/(1/ωC+Z₀)]

When the frequency f is high, the coefficient of reflection becomes −1 and thus the reflector voltage V1′ is represented by the equation V1′=V1×(−1)=−V1. Accordingly, when high frequency noise is propagated through the solid power supply pattern, the high frequency noise will be completely reflected by the capacitor 66 between the solid power supply pattern and the GND pattern. If this high frequency noise remains in the solid power supply pattern and enters the memory bus wiring via the parallel terminal end resistor of the memory bus wiring, the noise will be transmitted as a voltage to the receiving side of the memory bus signal, giving an adverse effect to logic determination, namely causing a malfunction. A similar adverse effect will be caused also when the noise enters the memory bus wiring or another power supply pattern due to cross-talk between the solid power supply pattern and the memory bus wiring or the other power supply pattern.

FIG. 6 shows a model of a printed circuit board according to the present invention, in which a series circuit is incorporated for consuming high frequency noise propagated through a VTT power supply pattern. More specifically, the printed circuit board shown here is composed of four layers: a first layer 61 as a top surface portion, a second layer 62 formed by a solid GND pattern, a third layer 63 formed by a solid power supply pattern connected to nowhere (hereafter referred to as the VTT power supply pattern), and a fourth layer 64 as a rear surface portion, and has a series circuit composed of a capacitor 66 and a resistor 67.

In FIG. 6, as in FIG. 5, wiring 61-1 and wiring 64-1 having a characteristic impedance of 50Ω are formed and arranged in the first layer 61 and the fourth layer 64, respectively. The wiring 61-1 in the first layer 61 and the wiring 64-1 in the fourth layer 64 are connected to each other through a via-hole 65 formed in the second layer (solid GND pattern) 62 and the third layer (floating solid pattern) 63 at a longitudinally central portion of the substrate.

A series circuit composed of the capacitor 66 and the resistor 67 is arranged and connected at each of the opposite ends of the substrate between the second layer (solid GND pattern) 62 and the third layer (VTT power supply pattern) 63. A substantially same value as the characteristic impedance Z₀ of the VTT power supply pattern is selected as a resistance value R of the resistor 67. An impedance Z of this series circuit is represented by the equation, |Z|=R+1/ωC. Thus, the coefficient of reflection between the VTT power supply pattern and the series circuit composed of the capacitor 66 and the resistor 67 is represented as (R+1/ωC−Z₀)/(R+1/ωC+Z₀). Therefore, the reflector voltage V1′ can be represented by the following equation as a function of a progressive wave voltage V1:

V1′=V1[(R+1/ωC−Z₀)/(R+1/ωC+Z₀)]

When the frequency f is high, 1/ωC becomes equal to zero, and hence the reflector voltage V1′ is represented by the equation, V1′=V1[(R−Z₀)/(R+Z₀)]. According to this equation, V1′ becomes equal to zero, if R=Z₀. Therefore, the high frequency noise will not be reflected by the series circuit composed of the capacitor 66 and the resistor 67 but consumed by the series circuit.

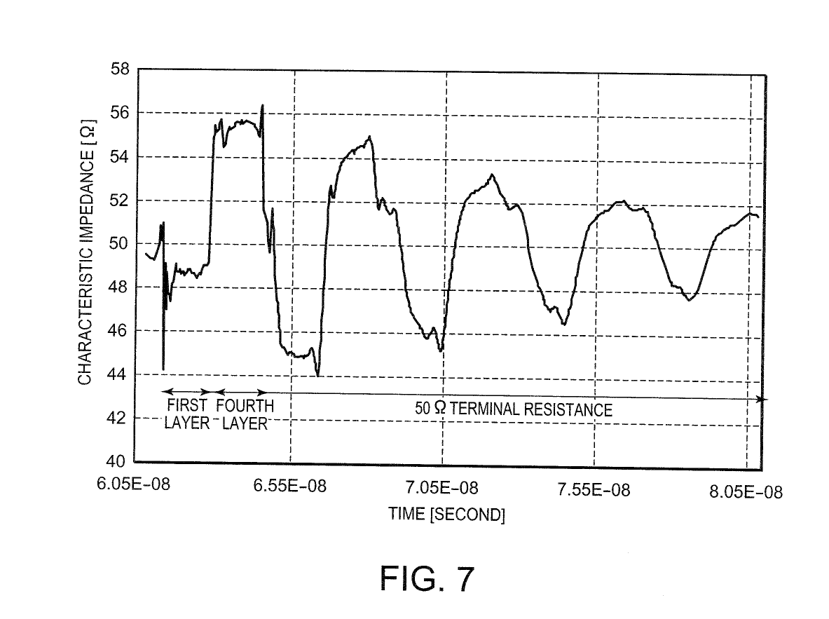

FIG. 7 shows a result of measuring time variation in the coefficient of reflection of the capacitor terminal end patterns at the opposite ends shown in FIG. 5, from the side of the first layer 61 by means of time domain reflectometry (TDR), and converting the coefficient of reflection into a characteristic impedance. While the characteristic impedance of the first layer wiring seems to be 50Ω, the characteristic impedance of the fourth layer wiring is observed higher than that. In addition, the 50Ω terminal resistance is observed to fluctuate. What is measured by TDR is a coefficient of reflection ρ=(reflected wave voltage)/(incident wave voltage), and a characteristic impedance of the object to be measured is represented as (TDR output impedance)×(1+ ρ)/(1−ρ), while the incident wave voltage is fixed. Therefore, it can be seen that the reflected wave voltage continues to fluctuate. This means that the voltage of the signal line on the board fluctuates. Specifically, as a signal is propagated to, in other words, electric charge is moved to the fourth layer wiring, a same quantity of holes are propagated to the solid power supply pattern on the third layer. The coefficient of reflection is −1, according to the description above, at a point of the end of the solid power supply pattern on the third layer which is connected to the solid GND pattern via the capacitor 66. Therefore, the signal is completely reflected at this point, and the reflected wave is propagated to the wiring. This explains the observation result described above. The characteristic impedance of the VTT power supply pattern on the third layer was calculated to be about 10Ω on the basis of the solid GND pattern of the second layer, and a capacitor of 0.1 μF was selected.

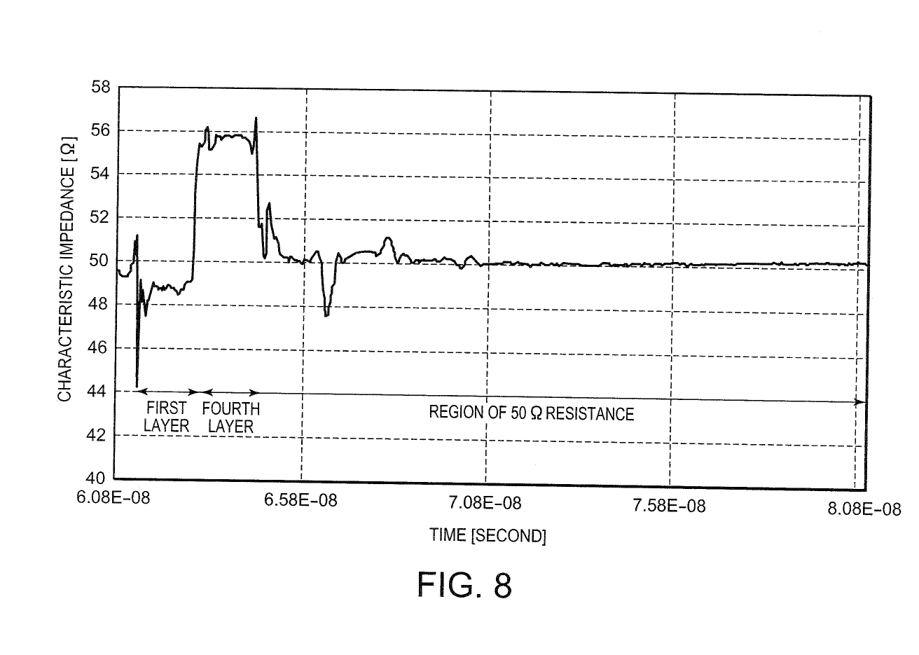

FIG. 8 shows a result of conducting TDR measurement on a printed circuit board having a series circuit composed of the capacitor 66 and the resistor 67 between the solid GND pattern in the second layer and the VTT power supply pattern in the third layer at the opposite ends of the circuit board. The 50Ω terminal resistance was observed to be 50Ω. This indicates that no reflection occurs since the coefficient of reflection of the series circuit composed of the capacitor 66 and the resistor 67 is zero. As a result, the re-propagation of the signal to the wiring as described above does not occur. The VTT power supply pattern in the third layer has a characteristic impedance of about 10Ω as described above. The capacitor 66 has a capacitance of 0.1 μF. As for the resistor 67, a small chip resistor having a characteristic impedance of 10Ω which is inexpensive and easy to obtain is selected for the reason that the characteristic impedance is close to that of the VTT power supply pattern.

As described above, the exemplary embodiment of the present invention provides advantageous effects as described below by connecting and arranging a series circuit composed of a capacitor and a resistor between a VTT power supply pattern and a GND pattern.

(1) Any noise generated in the VTT power supply pattern by operation of a high-speed DRAM or memory controller can be consumed by the series circuit, and thus the malfunction of the high-speed DRAM or memory controller can be suppressed.

(2) Since the high frequency noise can be suppressed by the circuit, the power supply pattern need not be shielded by the GND or the like, and thus the quantity of layers in the printed circuit board need not be increased. This enables provision of an inexpensive printed circuit board.

The present invention is not limited to the exemplary embodiment described above, but may be modified as follows.

The resistance value of the series circuit composed of the capacitor and the resistor and connected and arranged between the VTT power supply pattern and the GND pattern is desirably substantially equal to the characteristic impedance of the VTT power supply pattern.

This series circuit may be replaced with a set of N series circuits connected in parallel. In this case, it is preferable that, when the VTT power supply pattern has a characteristic impedance of Z₀, the resistance values of the respective resistors in the N series circuits are selected so as to satisfy the formula: 1/Z₀≈(1/R₁+1/R₂+ . . . +1/R_{N}) (where N is a natural number, R₁ denotes a resistance value of the resistor in the first series circuit, R₂ denotes a resistance value of the resistor in the second series circuit, . . . , and R_{N} is a resistance value of the resistor in the N-th series circuit). In this case, preferably, R₁=R₂= . . . =R_{N-1}=R_{N}.

The sequence of arranging the capacitor and the resistor may be in either order.

The high-speed DRAMs may be mounted on at least either the top surface portion or the rear surface portion of the printed circuit board.

The high-speed DRAMs may be those which require a VTT power supply pattern or a reference voltage (Vref) pattern to operate, such as DDR-SDRAMs and DDR2-SDRAMs.

The present invention is applicable to printed circuit boards in general on which a high-speed DRAM such as a DDR-SDRAM or DDR2-SDRAM is mounted.

What is claimed is:

1. A printed circuit board comprising a high-speed DRAM and a memory controller mounted thereon, with the high-speed DRAM being connected to the memory controller by means of memory bus wiring, the printed circuit board comprising:
a power supply pattern connected to the memory bus wiring via a parallel terminal end resistor; and
a series circuit formed by serially connecting, between the power supply pattern and a ground pattern, a capacitor and a resistor having a resistance value substantially equal to a characteristic impedance of the power supply pattern.

2. The printed circuit board according to claim 1, wherein the printed circuit board is a multilayer printed circuit board, the power supply pattern being formed under the memory bus wiring, the ground pattern being formed under the power supply pattern.

3. The printed circuit board according to claim 1, wherein the high-speed DRAM is mounted in plurality on the printed circuit board, and the series circuit is provided for each of the high-speed DRAMs.

4. The printed circuit board according to claim 1, wherein:
the high-speed DRAM is mounted in plurality on the printed circuit board;
the series circuit is provided in a plurality of N (N is a natural number) while being connected in parallel to each other; and
a resistance value of the resistor in each of the series circuits is selected such that, when a characteristic impedance of the power supply pattern is denoted by Z₀, the following formula is satisfied:
1/Z₀≈(1/R₁+1/R₂+ . . . 1/R_{N})
where R₁ denotes a resistance value of the resistor in a first one of the series circuits, R₂ a resistance value of the resistor of a second one of the series circuits, . . . , and R_{N} a resistance value of an N-th one of the series circuits.

5. The printed circuit board according to claim 3, wherein the plurality of the high-speed DRAMs are mounted at least one of a top surface portion and a rear surface portion of the printed circuit board.

6. The printed circuit board according to claim 1, wherein the high-speed DRAM requires the power supply pattern and a reference voltage pattern for its operation.

7. A method of reducing high frequency noise, which is applied to a printed circuit board comprising a high-speed DRAM and a memory controller mounted thereon, in which the high-speed DRAM and the memory controller are connected to each other through memory bus wiring, the printed circuit board further comprising a power supply pattern connected to the memory bus wiring, the method comprising:
providing a series circuit formed by serially connecting, between the power supply pattern and a ground pattern, a capacitor and a resistor having a resistance value substantially equal to a characteristic impedance of the power supply pattern; and
consuming, by the resistor, the high frequency noise generated in the power supply pattern due to operation of the high-speed DRAM or memory controller.
